(19) United States
(12) Patent Application Publication
(10) Pub. No.: US 2025/0098447 A1
(43) Pub. Date: Mar. 20, 2025

(54) DISPLAY SUBSTRATE AND DISPLAY DEVICE

(71) Applicants: Hefei BOE Joint Technology Co., Ltd., Hefei, Anhui (CN); BOE TECHNOLOGY GROUP CO., LTD., Beijing (CN)

(72) Inventors: Can Yuan, Beijing (CN); Zhidong Yuan, Beijing (CN); Liu Wu, Beijing (CN); Luke Ding, Beijing (CN); Yongqian Li, Beijing (CN); Cheng Xu, Beijing (CN); Dandan Zhou, Beijing (CN); Dacheng Zhang, Beijing (CN)

(73) Assignees: Hefei BOE Joint Technology Co., Ltd., Hefei, Anhui (CN); BOE TECHNOLOGY GROUP CO., LTD., Beijing (CN)

(21) Appl. No.: 18/558,248

(22) PCT Filed: Oct. 28, 2022
(86) PCT No.: PCT/CN2022/128241

§ 371 Date: Oct. 31, 2023

(51) Int. Cl. H10K 59/131; G09G 3/3225; H10K 59/122

(52) U.S. Cl. CPC H10K 59/131; G09G 3/3225; H10K 59/122; G09G 2300/0426; G09G 2300/0465; G09G 2300/0819; G09G 2300/0852; G09G 2300/0861; G09G 2310/08; G09G 2320/043

(57) ABSTRACT

A display substrate and a display device are provided. The display substrate includes: a base substrate, data lines and sub-pixels on the base substrate. The sub-pixels include a sub-pixel driving circuit and a light-emitting element including a first electrode. The sub-pixel driving circuit includes a driving transistor and a data writing transistor having a first electrode coupled to the data line through a second connection structure. A second electrode of the driving transistor is coupled to the first electrode through a first connection structure. The first and second connection structures are in a non-aperture region of the sub-pixel. Orthographic projections of the first and second connection structures onto the base substrate are arranged along a first direction. An orthographic projection of the second connection structure onto the base substrate and an aperture region of the sub-pixel are along a second direction which intersects the first direction.

### TECHNICAL FIELD

The present disclosure relates to the field of display technology, in particular to a display substrate and a display device.

### BACKGROUND

With the continuous development of display technologies, display products have a wider and wider range of applications, and display products with high resolution and high refresh rate are more and more popular. However, medium and large size display products are limited by the large load and cannot achieve the function of high refresh rate products well.

### SUMMARY

An objective of the present disclosure is to provide a display substrate and a display device.

In order to achieve the foregoing objective, the present disclosure provides the following technical solutions:
A first aspect of the present disclosure provides a display substrate, including: a base substrate, and a plurality of data lines and sub-pixels arranged on the base substrate; wherein the sub-pixels include a sub-pixel driving circuit and a light-emitting element; the sub-pixel driving circuit includes a driving transistor and a data writing transistor, and the light-emitting element includes a first electrode;
a second electrode of the driving transistor is coupled to the corresponding first electrode through a first connection structure; a first electrode of the data writing transistor is coupled to the corresponding data line through a second connection structure;
the first connection structure and the second connection structure are both located in a non-aperture region of the sub-pixel, and an orthographic projection of the first connection structure onto the base substrate is arranged with an orthographic projection of the second connection structure onto the base substrate along a first direction;
the orthographic projection of the second connection structure onto the base substrate is arranged with an aperture region of the sub-pixel along a second direction, and the second direction intersects with the first direction.

Optionally, the first connection structure includes: a second conductive connection portion, a first via-hole structure, a fifth conductive connection portion and a second via-hole structure;
the second conductive connection portion is coupled to the second electrode of the driving transistor, the second conductive connection portion is coupled to the fifth conductive connection portion through the first via-hole structure, and the fifth conductive connection portion is coupled to the corresponding first electrode through the second via-hole structure.

Optionally, the second connection structure includes: a fourth conductive connection portion and a third via-hole structure; the fourth conductive connection portion is coupled to the first electrode of the data writing transistor, and the fourth conductive connection portion is coupled to the corresponding data line through the third via-hole structure.

Optionally, the display substrate further includes a first organic layer and a second organic layer sequentially stacked in a direction away from the base substrate, the first via-hole structure passes through the first organic layer, and the second via-hole structure passes through the second organic layer:
the second conductive connection portion is located between the first organic layer and the base substrate, and the fifth conductive connection portion is located between the first organic layer and the second organic layer.

Optionally, the third via-hole structure passes through the first organic layer and the fourth conductive connection portion is located between the first organic layer and the base substrate.

Optionally, the display substrate further includes: a first passivation layer and a second passivation layer; the first passivation layer is located between the first organic layer and the second passivation layer, the second passivation layer is located between the first passivation layer and the second organic layer;
the first via-hole structure and the third via-hole structure both pass through the first passivation layer, and the second via-hole structure passes through the second passivation layer; the fifth conductive connection portion is located between the first passivation layer and the second passivation layer.

Optionally, the display substrate further includes: an auxiliary electrode, a third connection structure, and a second electrode layer; the auxiliary electrode is coupled to the second electrode layer through the third connection structure:
the third connection structure is located in the non-aperture region of the sub-pixel, and the orthographic projection of the third connection structure onto the base substrate is arranged with the orthographic projection of the first connection structure onto the base substrate along the first direction.

Optionally, the display substrate further includes: the auxiliary electrode, the third connection structure, and the second electrode layer; the auxiliary electrode is coupled to the second electrode layer through the third connection structure:
the third connection structure is located in the non-aperture region of the sub-pixel, and the orthographic projection of the third connection structure onto the base substrate is at least partly staggered from the orthographic projection of the first connection structure onto the base substrate.

Optionally, the display substrate further includes the second organic layer and a pixel definition layer sequentially stacked in a direction away from the base substrate:
the third connection structure includes: a fourth via-hole structure, a connecting pattern and a fifth via-hole structure; the auxiliary electrode is located between the second organic layer and the base substrate, at least a portion of the second electrode layer is located on a side of the pixel definition layer facing away from the base substrate, at least a portion of the connecting pattern is located between the second organic layer and the pixel definition layer, the fourth via-hole structure passes through the second organic layer, and the fifth via-hole structure passes through the pixel definition layer;
the connecting pattern is coupled to the auxiliary electrode through the fourth via-hole structure, and the connecting pattern is coupled to the second electrode layer through the fifth via-hole structure.

Optionally, the plurality of sub-pixels are divided into a plurality of repeating units distributed in an array, each repeating unit includes two sub-units arranged along the first direction, and each sub-unit includes the plurality of sub-pixels arranged along the first direction:
the orthographic projection of the auxiliary electrode onto the base substrate is located between the orthographic projections of the two sub-units onto the base substrate.

Optionally, the display substrate further includes a power line and a power compensation line:
the sub-pixel driving circuit further includes a light-emitting control transistor; a first electrode of the light-emitting control transistor is coupled to the power compensation line, and a second electrode of the light-emitting control transistor is coupled to a first electrode of the driving transistor;
the power compensation line is coupled to the power line through a sixth via-hole structure, and the sixth via-hole structure is located in the non-aperture region of the sub-pixel.

Optionally, the display substrate further includes the first organic layer, the power compensation line is located between the first organic layer and the base substrate, the power line is located on a side of the first organic layer facing away from the base substrate, and the sixth via-hole structure passes through the first organic layer.

Optionally, the orthographic projection of the power line onto the base substrate is alternately arranged along the first direction with the orthographic projection of the repeating unit on the base substrate.

Optionally, the display substrate further includes: a plurality of light-emitting control lines, the power line, an initialization signal line, a reference signal line, a plurality of first scan lines, a plurality of second scan lines, a plurality of third scan lines and a plurality of partition control lines:
the sub-pixel driving circuit further includes: a compensation transistor, a reset transistor, the light-emitting control transistor, a writing control transistor and a storage capacitor;
a gate electrode of the data writing transistor is coupled to the corresponding first scan line, and a second electrode of the data writing transistor is coupled to a first electrode of the writing control transistor;
a second electrode of the writing control transistor is coupled to a gate electrode of the driving transistor, and a gate electrode of the writing control transistor is coupled to the corresponding partition control line;
a gate electrode of the compensation transistor is coupled to the corresponding second scan line, a first electrode of the compensation transistor is coupled to the reference signal line, and a second electrode of the compensation transistor is coupled to the first electrode of the writing control transistor;
a gate electrode of the reset transistor is coupled to the corresponding third scan line, a first electrode of the reset transistor is coupled to the initialization signal line, and a second electrode of the reset transistor is coupled to the second electrode of the driving transistor;
a gate electrode of the light-emitting control transistor is coupled to the corresponding light-emitting control line, the first electrode of the light-emitting control transistor is coupled to the power line, and the second electrode of the light-emitting control transistor is coupled to the first electrode of the driving transistor;
a first electrode plate of the storage capacitor is coupled to the gate electrode of the driving transistor, and a second electrode plate of the storage capacitor is coupled to the second electrode of the driving transistor.

Based on the technical solution of the foregoing display substrate, a second aspect of the present disclosure provides a display device, including the foregoing display substrate.

### BRIEF DESCRIPTION OF THE DRAWINGS

The drawings described herein are used to provide a further understanding of the present disclosure and constitute a part of the disclosure. The exemplary embodiments of the disclosure and the descriptions thereof are used to explain the disclosure, and do not constitute improper limitations to the disclosure. In the drawings:

FIG. 1 is a circuit diagram of a sub-pixel driving circuit according to an embodiment of the present disclosure;

FIG. 2 is a circuit structural diagram of a repeating unit according to an embodiment of the present disclosure:

FIG. 3 is a schematic diagram of an equivalent resistance and capacitance of a partition control line according to an embodiment of the present disclosure:

FIG. 4 is a driving timing diagram according to an embodiment of the present disclosure:

FIG. 5 is a schematic diagram of a layout of an active layer and a first gate metal layer of a repeating unit according to an embodiment of the present disclosure:

FIG. 6 is a schematic diagram of a layout with an addition of a second gate metal layer based on FIG. 5:

FIG. 7 is a schematic diagram of a layout of a second gate metal layer in FIG. 6:

FIG. 8 is a schematic diagram of a layout with an addition of a first source-drain metal layer based on FIG. 6:

FIG. 9 is a schematic diagram of a layout of via holes formed on an interlayer insulating layer in FIG. 8:

FIG. 10 is a schematic diagram of a layout of a first source-drain metal layer in FIG. 8;

FIG. 11 is a schematic diagram of a layout with an addition of a second source-drain metal layer based on FIG. 8:

FIG. 12 is a schematic diagram of a layout of via holes formed on a first organic layer in FIG. 11:

FIG. 13 is a schematic diagram of a layout of via holes formed on a first passivation layer in FIG. 11:

FIG. 14 is a schematic diagram of a layout of a second source-drain metal layer in FIG. 11:

FIG. 15 is a schematic diagram of a layout with an addition of a first electrode layer based on FIG. 11:

FIG. 16 is a schematic diagram of a layout of via holes formed on a second passivation layer in FIG. 15:

FIG. 17 is a schematic diagram of a layout of via holes formed on a second organic layer in FIG. 15:

FIG. 18 is a schematic diagram of a layout of a first electrode layer in FIG. 15:

FIG. 19 is a schematic diagram of a layout with an addition of a first pixel definition layer based on FIG. 15:

FIG. 20 is a schematic diagram of a layout of a first pixel definition layer in FIG. 19:

FIG. 21 is a schematic diagram of a layout with an addition of an aperture in a second pixel definition layer based on FIG. 19:

FIG. 22 is a schematic diagram of a layout of an aperture in a second pixel definition layer in FIG. 21:

FIG. 23 is a schematic diagram of an aperture in a second pixel definition layer based on FIG. 19; and

FIG. 24 is a schematic diagram of a cross-sectional along A1A2 direction in FIG. 23.

### DETAILED DESCRIPTION

In order to further describe the display substrate and the display device provided by the embodiments of the present disclosure, a detailed description is made below combining with the accompanying drawings.

Due to the large load limitation of medium and large size display products, it is not possible to achieve high refresh rate product functions well. Therefore, it is necessary to add metal layers and thick insulating layers for wiring to reduce the load impact. And adding a thick insulating layer requires forming deep via holes on the insulating layer. The deep via holes can affect the flatness of the light-emitting functional layer, thereby reducing the aperture ratio of the display product and affecting the service life of the display product.

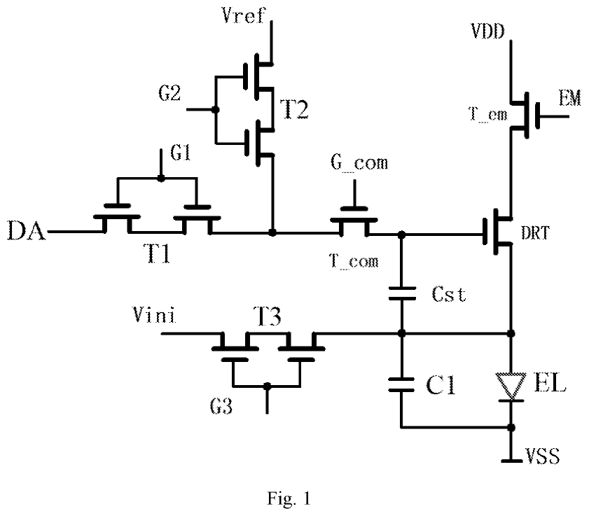

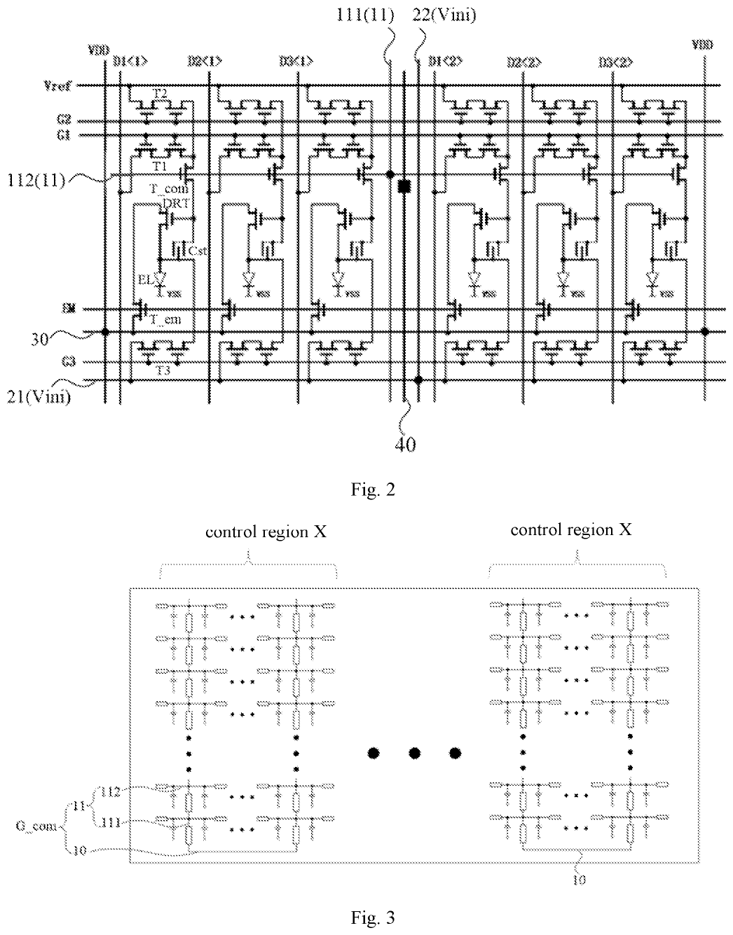

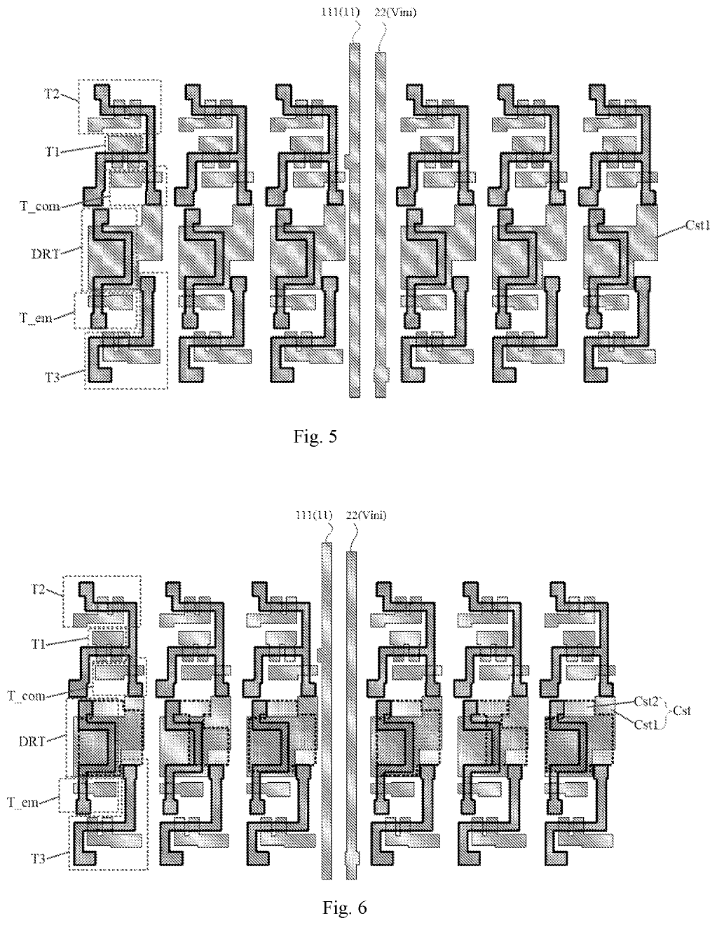

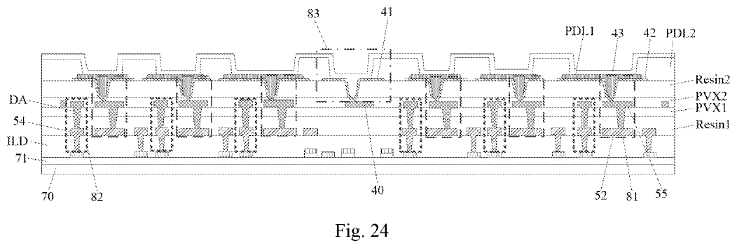

Referring to FIG. 1, FIG. 2, FIG. 5, FIG. 23 and FIG. 24, one embodiment of the present disclosure provides a display substrate, including: a base substrate, and a plurality of data lines DA and a plurality of sub-pixels arranged on the base substrate; the sub-pixels include a sub-pixel driving circuit and a light-emitting element EL; the sub-pixel driving circuit includes a driving transistor DRT and a data writing transistor T1, and the light-emitting element EL includes a first electrode:
a second electrode of the driving transistor DRT is coupled to the corresponding first electrode through a first connection structure 81: a first electrode of the data writing transistor T1 is coupled to the corresponding data line DA through a second connection structure 82;
the first connection structure 81 and the second connection structure 82 are both located in a non-aperture region 61 of the sub-pixel, and an orthographic projection of the first connection structure 81 on the base substrate is arranged with an orthographic projection of the second connection structure 82 on the base substrate along a first direction;
the orthographic projection of the second connection structure 82 on the base substrate is arranged with an aperture region 60 of the sub-pixel along a second direction, and the second direction intersects with the first direction.

Exemplarily, the plurality of data lines DA are arranged along the first direction, and the data lines DA include at least portions extending along the second direction. The plurality of sub-pixels are distributed in an array, the plurality of sub-pixels are divided into a plurality of columns of sub-pixel columns, and each sub-pixel column includes respective sub-pixels coupled to the corresponding data lines DA respectively.

Exemplarily, the sub-pixels include a sub-pixel driving circuit and a light-emitting element, and the sub-pixel driving circuit is coupled to a first electrode included by the light-emitting element for providing a driving signal to the first electrode of the light-emitting element to drive the light-emitting element to emit light.

Exemplarily, the data line DA and the first electrode are both located on a side of the sub-pixel driving circuit facing away from the base substrate. There is a thick insulating layer between the data line DA and the first electrode of the data writing transistor T1, and there is also a thick insulating layer between the first electrode and the second electrode of the driving transistor DRT. Therefore, the first connection structure 81 and the second connection structure 82 both include a deep via-hole structure.

According to the specific structure of the foregoing display substrate, in the display substrate provided by the embodiments of the present disclosure, by arranging the first connection structure 81 and the second connection structure 82 both to be located in the non-aperture region of the sub-pixel, it is avoided that the first connection structure 81 and the second connection structure 82 occupy the space in the aperture region, ensuring the aperture ratio of the display substrate, and avoiding the first connection structure 81 and the second connection structure 82 affecting the flatness of the light-emitting element.

Moreover, in the display substrate provided by the embodiments of the present disclosure, by arranging the orthographic projection of the first connection structure 81 on the base substrate to be arranged with the orthographic projection of the second connection structure 82 on base substrate along the first direction and arranging the orthographic projection of the second connection structure 82 on the base substrate to be arranged with the aperture region of the sub-pixel along the second direction, the first connection structure 81 and the second connection structure 82 are both located on the same side of the aperture region along the second direction and the first connection structure 81 and the second connection structure 82 occupy a small space in the second direction. It can concentrate shielding for the first connection structure 81 and the second connection structure 82. Thus, the size of the aperture region in the second direction can be optimized, effectively improving the aperture ratio of the display substrate, and improving the service life of the display substrate.

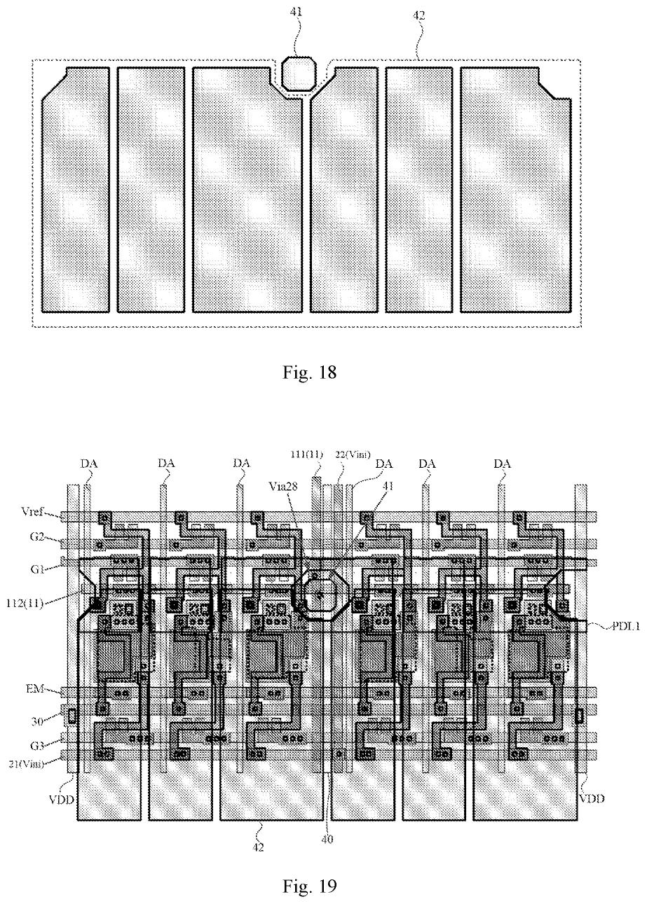

As shown in FIG. 8 to FIG. 18, FIG. 23 and FIG. 24, in some embodiments, the first connection structure 81 includes: a second conductive connection portion 52, a first via-hole structure, a fifth conductive connection portion 55 and a second via-hole structure.

The second conductive connection portion 52 is coupled to the second electrode of the driving transistor DRT, the second conductive connection portion 52 is coupled to the fifth conductive connection portion 55 through the first via-hole structure, and the fifth conductive connection portion 55 is coupled to the corresponding first electrode (the first electrode layer 42 includes a plurality of first electrodes) through the second via-hole structure.

Exemplarily, the first via-hole structure includes a seventeenth via hole Via17 and a twentieth via hole Via20. The second via-hole structure includes a twenty-fourth via hole Via24 and a twenty-sixth via hole Via26. The second conductive connection portion 52 is made of the first source-drain metal layer in the display substrate, and the fifth conductive connection portion 55 is made of the second source-drain metal layer in the display substrate.

As shown in FIG. 8 to FIG. 18, FIG. 23 and FIG. 24, in some embodiments, the second connection structure 82 includes: a fourth conductive connection portion 54 and a third via-hole structure. The fourth conductive connection portion 54 is coupled to a first electrode of the data writing transistor T1, and the fourth conductive connection portion 54 is coupled to the corresponding data line DA through the third via-hole structure.

Exemplarily, the third via-hole structure includes a sixteenth via hole Via16 and a nineteenth via hole Via19. The fourth conductive connection portion 54 is made of the first source-drain metal layer in the display substrate.

As shown in FIG. 24, in some embodiments, the display substrate includes: a buffer layer 71, an active layer, a first gate electrode insulating layer, a first gate metal layer, a second gate electrode insulating layer, a second gate metal layer, an interlayer insulating layer ILD, a first source-drain metal layer, a first organic layer Resin1, a first passivation layer PVX1, a second source-drain metal layer, a second passivation layer PVX2, a second organic layer Resin2, a first electrode layer 42, a first pixel definition layer PDL1, a second pixel definition layer PDL2, a light-emitting functional layer, a second electrode layer 43, and an encapsulation layer. The second electrode layer 43 receives a negative power supply signal VSS.

As shown in FIG. 8 to FIG. 18, FIG. 23 and FIG. 24, in some embodiments, the display substrate further includes a first organic layer and a second organic layer sequentially stacked in a direction away from the base substrate, the first via-hole structure passes through the first organic layer, and the second via-hole structure passes through the second organic layer:
the second conductive connection portion 52 is located between the first organic layer and the base substrate, and the fifth conductive connection portion 55 is located between the first organic layer and the second organic layer.

The first organic layer and the second organic layer are both thick insulating layers, so the first via-hole structure and the second via-hole structure are both deep via-hole structures. By arranging the first connection structure 81 to be located in the non-aperture region of the sub-pixel, the first via-hole structure and the second via-hole structure are both located in the non-aperture region, it is avoided that the first via-hole structure and the second via-hole structure occupy the space of the aperture region, ensuring the aperture ratio of the display substrate, and avoiding the first via-hole structure and the second via-hole structure affecting the flatness of the light-emitting element.

As shown in FIG. 8 to FIG. 18, FIG. 23 and FIG. 24, in some embodiments, the third via-hole structure passes through the first organic layer, and the fourth conductive connection portion 54 is located between the first organic layer and the base substrate.

The first organic layer is a thick insulating layer, so the third via-hole structure is a deep via-hole structure. By arranging the second connection structure 82 to be located in the non-aperture region of the sub-pixel, the third via-hole structure is located in the non-aperture region, it is avoided that the third via-hole structure occupy the space of the aperture region, ensuring the aperture ratio of the display substrate, and avoiding the third via-hole structure affecting the flatness of the light-emitting element.

In the display substrate provided by the foregoing embodiments, by arranging the orthographic projection of the first connection structure 81 on the base substrate to be arranged with the orthographic projection of the second connection structure 82 on the base substrate along the first direction and arranging the orthographic projection of the second connection structure 82 on the base substrate to be arranged with the aperture region of the sub-pixel along the second direction, the orthographic projections of the first via-hole structure, the second via-hole structure, and the third via-hole structure on the base substrate are all located on the same side of the aperture region along the second direction, and the first via-hole structure, the second via-hole structure and the third via-hole structure occupy a small space along the second direction. Thus, the size of the aperture region along the second direction can be optimized, effectively improving the aperture ratio of the display substrate, and improving the service life of the display substrate.

As shown in FIG. 8 to FIG. 18, FIG. 23 and FIG. 24, in some embodiments, the display substrate further includes: a first passivation layer and a second passivation layer; the first passivation layer is located between the first organic layer and the second passivation layer, and the second passivation layer is located between the first passivation layer and the second organic layer;
the first via-hole structure and the third via-hole structure both pass through the first passivation layer, and the second via-hole structure passes through the second passivation layer; the fifth conductive connection portion 55 is located between the first passivation layer and the second passivation layer.

In the display substrate provided by the foregoing embodiments, by arranging the display substrate to further include the first passivation layer and the second passivation layer, and arranging the fifth conductive connection portion 55 to be located between the first passivation layer and the second passivation layer, the electrical conductivity of the fifth conductive connection portion 55 can be better ensured.

As shown in FIG. 8 to FIG. 18, FIG. 23 and FIG. 24, in some embodiments, the display substrate further includes: an auxiliary electrode 40, a third connection structure 83, and a second electrode layer 43; the auxiliary electrode 40 is coupled to the second electrode layer 43 through the third connection structure 83:
the third connection structure 83 is located in the non-aperture region 61 of the sub-pixel, and the orthographic projection of the third connection structure 83 on the base substrate is arranged with the orthographic projection of the first connection structure 81 on the base substrate along the first direction.

Exemplarily, the display substrate includes a plurality of auxiliary electrodes 40 arranged along the first direction, and the auxiliary electrodes 40 include at least a portion extending along the second direction.

Exemplarily, there is a thick insulating layer between the auxiliary electrode 40 and the second electrode layer, and the third connection structure 83 includes a deep via-hole structure that can pass through the thick insulating layer.

In the display substrate provided by the foregoing embodiments, by arranging the third connection structure 83 to be located in the non-aperture region 61 of the sub-pixel, it is avoided that the third connection structure 83 occupies the space of the aperture region 60, ensuring the aperture ratio of the display substrate, and avoiding the third connection structure 83 affecting the flatness of the light-emitting element.

Moreover, in the display substrate provided by the foregoing embodiments, by arranging the orthographic projection of the third connection structure 83 on the base substrate to be arranged with the orthographic projection of the first connection structure 81 on the base substrate along the first direction, the first connection structure 81 and the third connection structure 83 are both located on the same side of the aperture region 60 along the second direction, and the first connection structure 81 and the third connection structure 83 occupy a small space along the second direction. Thus, the size of the aperture region 60 along the second direction can be optimized, effectively improving the aperture ratio of the display substrate, and improving the service life of the display substrate.

As shown in FIG. 8 to FIG. 18, FIG. 23 and FIG. 24, in some embodiments, the display substrate further includes: an auxiliary electrode 40, a third connection structure 83, and a second electrode layer; the auxiliary electrode 40 is coupled to the second electrode layer 43 through the third connection structure 83:
the third connection structure 83 is located in the non-aperture region of the sub-pixel, and the orthographic projection of the third connection structure 83 on the base substrate is at least partly staggered from the orthographic projection of the first connection structure 81 on the base substrate 34.

In the display substrate provided by the foregoing embodiments, by arranging the orthographic projection of the third connection structure 83 on the base substrate to be at least partly staggered from the orthographic projection of the first connection structure 81 on the base substrate, the layout space of the non-aperture region is utilized better, and the layout difficulty of the first connection structure 81 and the third connection structure 83 is reduced.

As shown in FIG. 8 to FIG. 18, FIG. 23 and FIG. 24, in some embodiments, the display substrate further includes the second organic layer and a pixel definition layer sequentially stacked in a direction away from the base substrate:
the third connection structure 83 includes: a fourth via-hole structure, a connecting pattern 41 and a fifth via-hole structure; the auxiliary electrode 40 is located between the second organic layer and the base substrate, at least a portion of the second electrode layer is located on a side of the pixel definition layer facing away from the base substrate, at least a portion of the connecting pattern 41 is located between the second organic layer and the pixel definition layer, the fourth via-hole structure passes through the second organic layer, and the fifth via-hole structure passes through the pixel definition layer;
the connecting pattern 41 is coupled to the auxiliary electrode 40 through the fourth via-hole structure, and the connecting pattern 41 is coupled to the second electrode layer through the fifth via-hole structure.

Exemplarily, the pixel definition layer includes a first pixel definition layer and a second pixel definition layer in a stacked arrangement, and the first pixel definition layer is located between the base substrate and the second pixel definition layer. At least a portion of the second electrode layer is located on a side of the second pixel definition layer facing away from the base substrate, and at least a portion of the connecting pattern 41 is located between the second organic layer and the first pixel definition layer.

Exemplarily, the fourth via-hole structure includes a twenty-fifth via hole Via25 and a twenty-seventh via hole Via27. The fifth via-hole structure includes a twenty-eighth via hole Via28 and a twenty-ninth via hole Via29.

Exemplarily, the connecting pattern 41 is arranged in the same layer as the first electrode layer 42. Exemplarily, the connecting pattern 41 can be made of the same material as the first electrode layer, such as using indium tin oxide material, or it can be made of different materials that can meet the performance of conductive connection.

In the display substrate provided by the foregoing embodiments, by arranging the second electrode layer to be coupled to multiple auxiliary electrodes 40 through connecting patterns 41, the voltage drop of the second electrode layer is effectively reduced.

As shown in FIG. 21, in some embodiments, the plurality of sub-pixels are divided into a plurality of repeating units distributed in an array, each repeating unit includes two sub-units arranged along the first direction, and each sub-unit includes a plurality of sub-pixels arranged along the first direction:
the orthographic projection of the auxiliary electrode 40 on the base substrate is located between the orthographic projections of the two sub-units onto the base substrate.

Exemplarily, the display substrate includes a plurality of repeating units, the plurality of repeating units are distributed in an array, and can be divided into a plurality of columns of repeating unit columns arranged along the first direction, and each column of repeating unit columns includes a plurality of repeating units arranged along the second direction. The repeating unit includes a plurality of sub-pixels arranged along the first direction, for example: the repeating unit includes six sub-pixels arranged along the first direction, which include BRGBRG arranged along the first direction, wherein B represents a blue sub-pixel, R represents a red sub-pixel, and G represents a green sub-pixel. A group of BRG represents a sub-unit.

Exemplarily, the plurality of sub-pixels included in the plurality of repeating units are distributed in an array, the plurality of sub-pixels can be divided into a plurality of columns of sub-pixel columns, and the plurality of columns of sub-pixel columns correspond to the plurality of data lines DA included in the display substrate one by one.

By arranging the orthographic projection of the auxiliary electrode 40 on the base substrate to be located between the orthographic projections of the two sub-units onto the base substrate, the layout space is utilized better and the layout difficulty of the auxiliary electrode 40 is reduced.

As shown in FIG. 8 to FIG. 18, FIG. 23 and FIG. 24, in some embodiments, the display substrate further includes a power line VDD and a power compensation line 30;
the sub-pixel driving circuit further includes a light-emitting control transistor T_em: a first electrode of the light-emitting control transistor T_em is coupled to the power compensation line 30, and a second electrode of the light-emitting control transistor T_em is coupled to a first electrode of the driving transistor DRT;
the power compensation line 30 is coupled to the power line VDD through a sixth via-hole structure, and the sixth via-hole structure is located in the non-aperture region of the sub-pixel.

Exemplarily, the plurality of power lines VDD are arranged along the first direction, and the power lines VDD include at least a portion extending along the second direction. Along the first direction, the power lines VDD are alternately arranged with the repeating unit columns.

Exemplarily, the sixth via-hole structure includes an eighteenth via hole Via18 and a twenty-first via hole Via21.

In some embodiments, the display substrate further includes the first organic layer, the power compensation line 30 is located between the first organic layer and the base substrate, the power line VDD is located on a side of the first organic layer facing away from the base substrate, and the sixth via-hole structure passes through the first organic layer.

By arranging the sixth via-hole structure in the non-aperture region of the sub-pixel, it is avoided that the sixth connection structure occupy the space of the aperture region, ensuring the aperture ratio of the display substrate, and avoiding the sixth connection structure affecting the flatness of the light-emitting element.

In some embodiments, the orthographic projection of the power line VDD on the base substrate is alternately arranged along the first direction with the orthographic projection of the repeating unit on the base substrate.

As shown in FIG. 1, FIG. 2, FIG. 8 to FIG. 18, FIG. 23 and FIG. 24, in some embodiments, the display substrate further includes: a plurality of light-emitting control lines EM, a power line VDD, an initialization signal line Vini, a reference signal line Vref, a plurality of first scan lines G1, a plurality of second scan lines G2, a plurality of third scan lines G3 and a plurality of partition control lines:
the sub-pixel driving circuit further includes: a compensation transistor T2, a reset transistor T3, a light-emitting control transistor T_em, a writing control transistor T_com and a storage capacitor Cst;
a gate electrode of the data writing transistor T1 is coupled to the corresponding first scan line G1, and a second electrode of the data writing transistor T1 is coupled to a first electrode of the writing control transistor T_com;
a second electrode of the writing control transistor T_com is coupled to a gate electrode of the driving transistor DRT, and a gate electrode of the writing control transistor T_com is coupled to the corresponding partition control line;
a gate electrode of the compensation transistor T2 is coupled to the corresponding second scan line G2, a first electrode of the compensation transistor T2 is coupled to the reference signal line Vref, and a second electrode of the compensation transistor T2 is coupled to a first electrode of the writing control transistor T_com;
a gate electrode of the reset transistor T3 is coupled to the corresponding third scan line G3, a first electrode of the reset transistor T3 is coupled to the initialization signal line Vini, and a second electrode of the reset transistor T3 is coupled to a second electrode of the driving transistor DRT;
a gate electrode of the light-emitting control transistor T_em is coupled to the corresponding light-emitting control line EM, a first electrode of the light-emitting control transistor T_em is coupled to the power line VDD, and a second electrode of the light-emitting control transistor T_em is coupled to a first electrode of the driving transistor DRT;
a first electrode plate Cst1 of the storage capacitor Cst is coupled to a gate electrode of the driving transistor DRT, and a second electrode plate Cst2 of the storage capacitor Cst is coupled to a second electrode of the driving transistor DRT.

Exemplarily, the initialization signal line Vini includes a plurality of first initial portions 21 and a plurality of second initial portions 22. The plurality of first initial portions 21 are arranged along the second direction. The plurality of second initial portions 22 are arranged along the first direction. The first initial portion 21 includes at least a portion extending along the first direction. The second initial portion 22 includes at least a portion extending along the second direction. The first initial portion 21 is coupled to each of the second initial portions 22 respectively. So that, the initialization signal line Vini forms a grid-like structure, thereby effectively reducing the voltage drop of the initialization signal line Vini.

As shown in FIG. 5, exemplarily, the active layer is used to form the channel portions included in each of the transistors, a first electrode and a second electrode.

As shown in FIG. 5, exemplarily, the first gate metal layer is used to form the gate electrodes of each of the transistors, the first branch line 111 and the second initial portion 22.

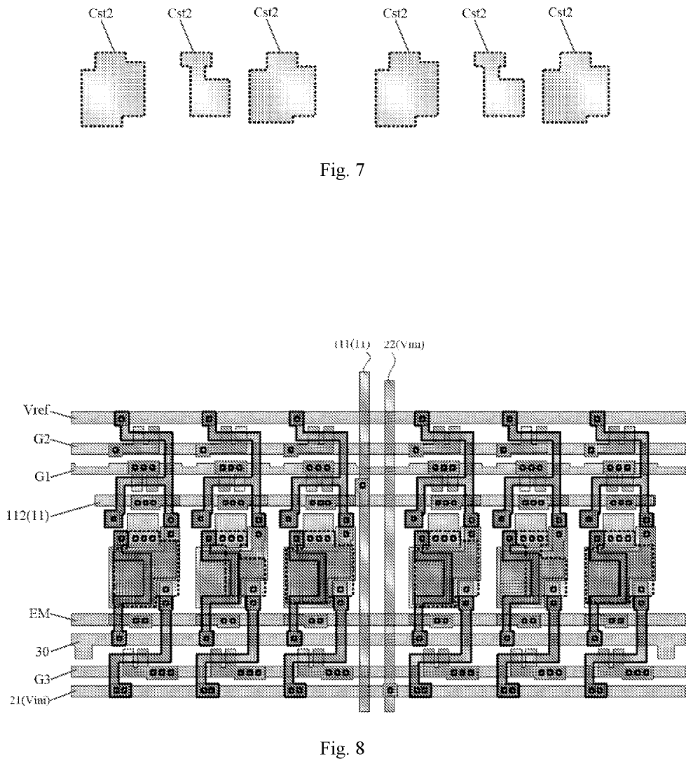

As shown in FIG. 7, exemplarily, the second gate metal layer is used for the second substrate of the storage capacitor Cst.

As shown in FIG. 10, exemplarily, the first source-drain metal layer is used to form some conductive connection portions, the reference signal line Vref, the first scan line G1, the second scan line G2, the third scan line G3, the light-emitting control line EM and the first initial portion 21. The reference signal line Vref, the second scan line G2, the first scan line G1, the second branch line 112, light-emitting control line EM, the power compensation line 30, the third scan line G3 and the first initial portion 21 coupled to the same repeating unit are arranged along the second direction in sequence.

Exemplarily, the reference signal line Vref, the first scan line G1, the second scan line G2, the third scan line G3 and the light-emitting control line EM all include at least a portion extending along the first direction.

As shown in FIG. 14, exemplarily, the second source-drain metal layer is used to form the power line VDD, the data line DA, some conductive connection portions and the auxiliary electrode 40. Using the second source-drain metal layer to make signal lines can effectively reduce the load of the signal lines and provide technical support for medium and large size display products. Exemplarily, the auxiliary electrode 40 includes at least a portion extending along the second direction, and the auxiliary electrode 40 is coupled to the second electrode layer through a connecting pattern 41 made of indium tin oxide material, thereby effectively reducing the voltage drop of the second electrode layer.

Since there are the first organic layer and the first passivation layer between the first source-drain metal layer and the second source-drain metal layer, the first source-drain metal layer and the second source-drain metal layer are relatively far apart from each other. It can effectively reduce the parasitic capacitance between the first source-drain meta layer and the second source-drain metal layer, thereby meeting the load demand of medium and large size display products and providing support for high refresh rate.

As shown in FIG. 1, exemplarily, the sub-pixel driving circuit includes: a data writing transistor T1, a writing control transistor T_com, a driving transistor DRT, a compensation transistor T2, a reset transistor T3, a light-emitting control transistor T_em, a storage capacitor Cst and an intrinsic capacitor C1 of the light-emitting element EL.

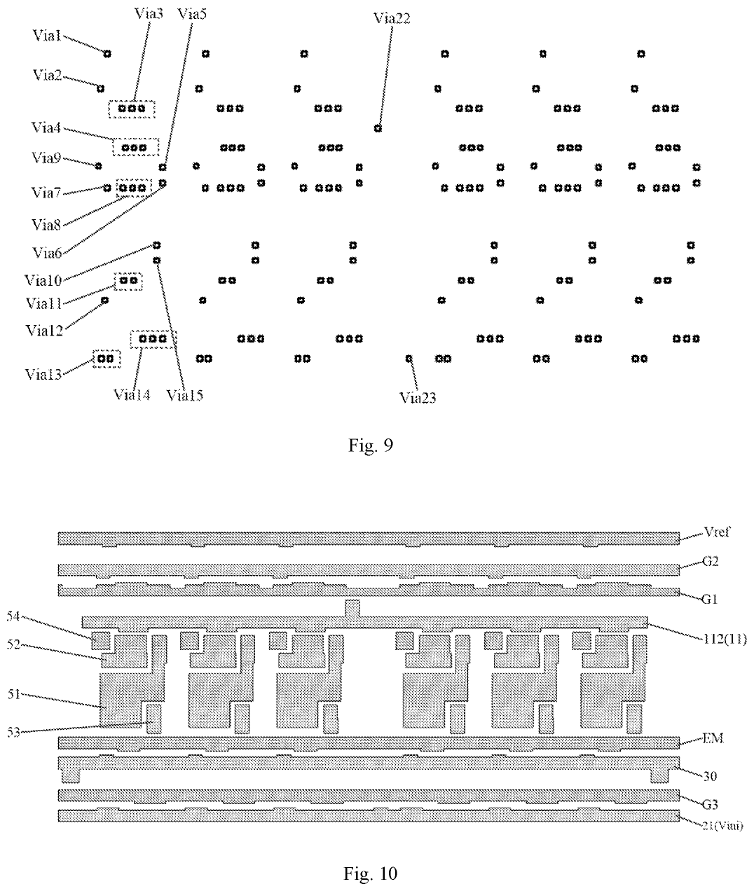

As shown in FIG. 9, it schematically shows via holes formed on the interlayer insulating layer. As shown in FIG. 5 to FIG. 10, a gate electrode of the compensation transistor T2 is coupled to the corresponding second scan line G2 through a second via hole Via2, and a first electrode of the compensation transistor T2 is coupled to the reference signal line Vref through a first via hole Via1.

A gate electrode of the data writing transistor T1 is coupled to the corresponding first scan line G1 through a third via hole Via3. A first electrode of the data writing transistor T1 is coupled to a fourth conductive connection portion 54 through a ninth via hole Via9.

A gate electrode of the writing control transistor T_com is coupled to a partition control line G_com through a fourth via hole Via4, and a second electrode of the writing control transistor T_com is coupled to a first conductive connection portion 51 through a fifth via hole Via5. The first conductive connection portion 51 is coupled to a gate electrode of the driving transistor DRT through a sixth via hole Via6. The gate electrode of the driving transistor DRT is reused as a first electrode plate Cst1 of the storage capacitor Cst.

A second electrode of the driving transistor DRT is coupled to a second conductive connection portion 52 through a seventh via hole Via7. The second conductive connection portion 52 is coupled to a second electrode plate Cst2 of the storage capacitor Cst through an eighth via hole Via8. The second electrode plate Cst2 of the storage capacitor Cst is coupled to a third conductive connection portion 53 through a tenth via hole Via10. The third conductive connection portion 53 is coupled to a second electrode of the reset transistor T3 through a fifteenth via hole Via15.

A gate electrode of the light-emitting control transistor T_em is coupled to the corresponding light-emitting control line EM through an eleventh via hole Via11. A first electrode of the light-emitting control transistor T_em is coupled to the power line VDD through a twelfth via hole Via12.

A gate electrode of the reset transistor T3 is coupled to the third scan line G3 through a fourteenth via hole Via14. A first electrode of the reset transistor T3 is coupled to the first initial portion 21 through a thirteenth via hole Via13.

The first branch line 111 is coupled to the second branch line 112 through a twenty-second via hole Via22. The first initial portion 21 is coupled to the second initial portion 22 through a twenty-third via hole Via23.

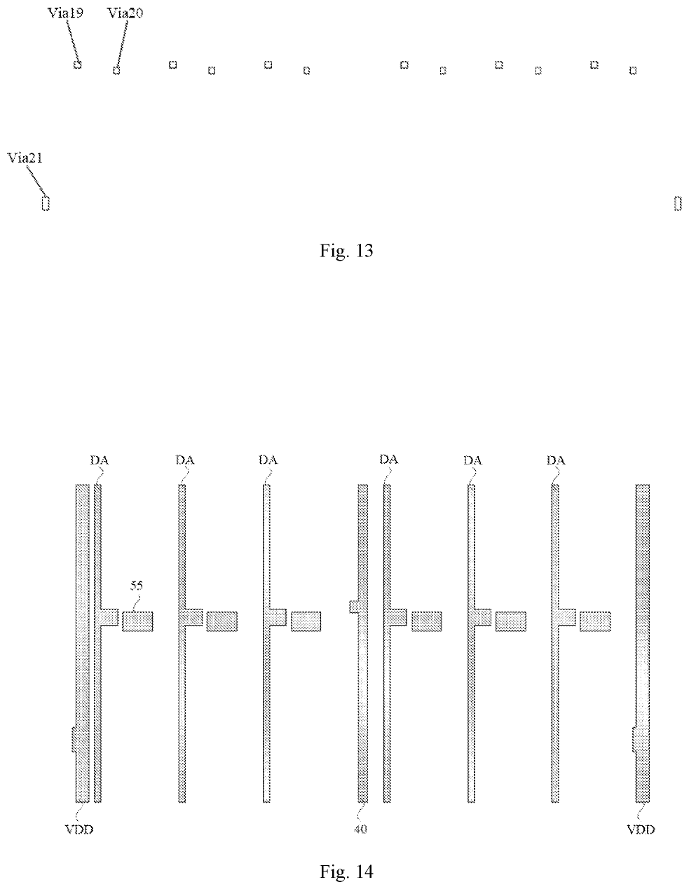

As shown in FIG. 12, a schematic diagram of via holes formed on the first organic layer is shown. As shown in FIG. 13, a schematic diagram of via holes formed on the first passivation layer is shown.

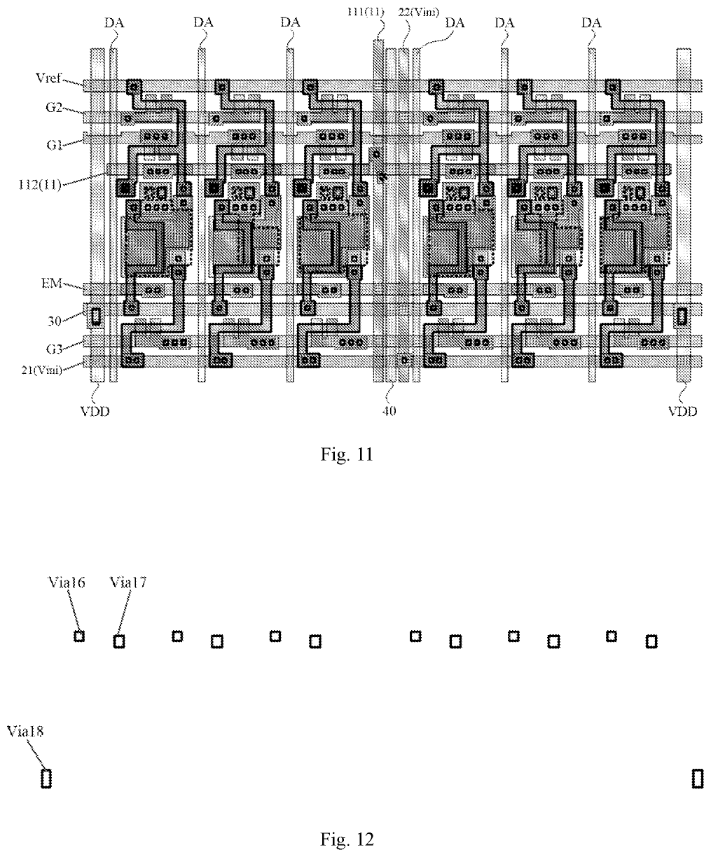

As shown in FIG. 11 to FIG. 14, the second conductive connection portion 52 is sequentially coupled to the fifth conductive connection portion 55 through the seventeenth via hole Via17 and the twentieth via hole Via20. The fourth conductive connection portion 54 is sequentially coupled to the data line DA through the sixteenth via hole Via16 and the nineteenth via hole Via19. The power compensation line 30 is sequentially coupled to the power line VDD through the eighteenth via hole Via18 and the twenty-first via hole Via21.

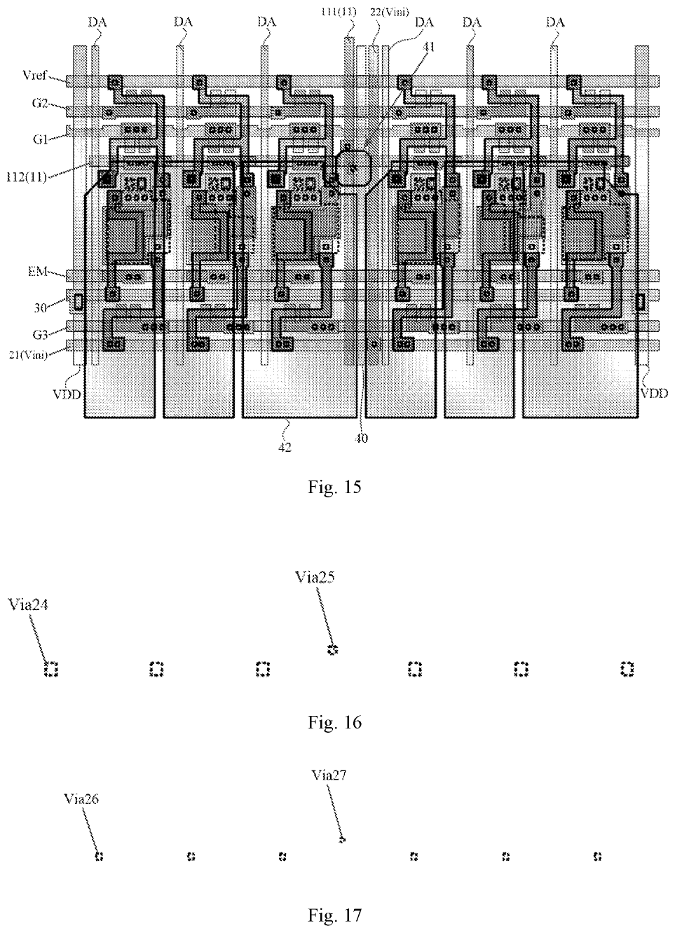

As shown in FIG. 16, a schematic diagram of via holes formed on the second passivation layer is shown. As shown in FIG. 17, a schematic diagram of via holes formed on the second organic layer is shown.

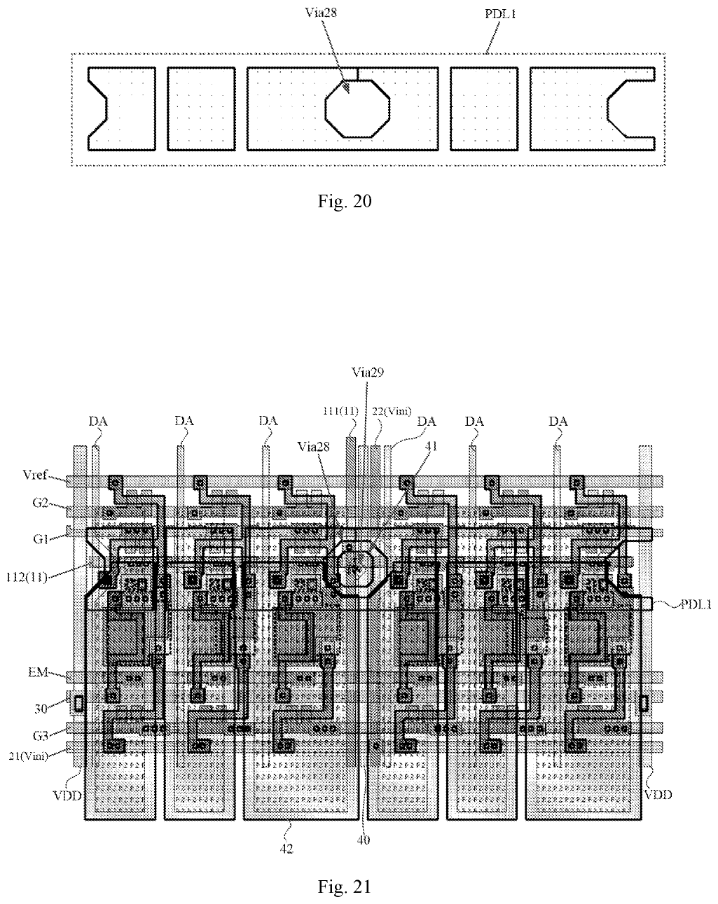

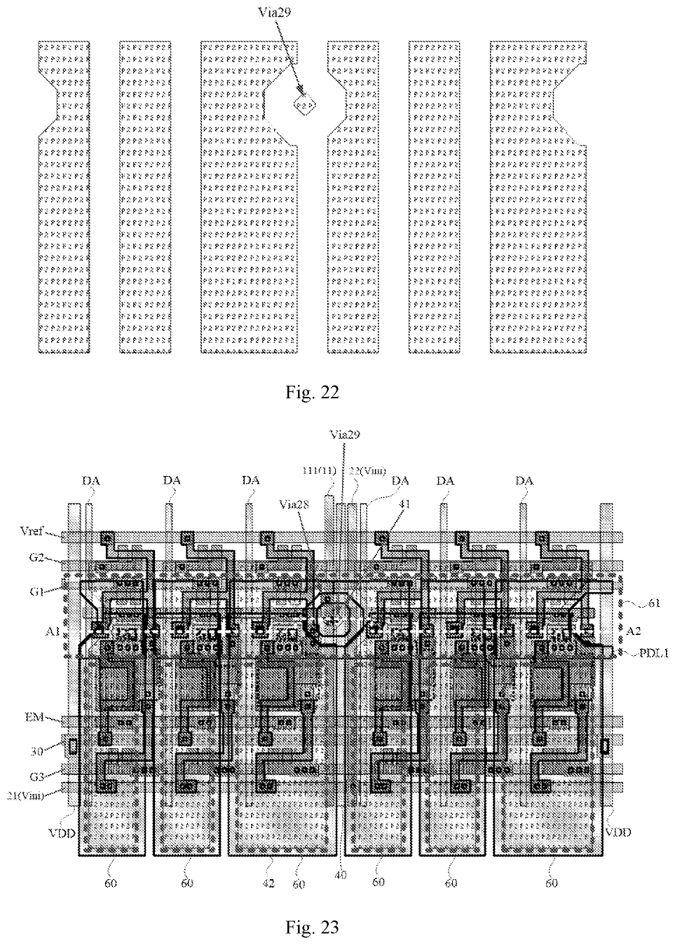

As shown in FIG. 15 to FIG. 22, the fifth conductive connection portion 55 is sequentially coupled to the corresponding first electrode in the first electrode layer 42 through the twenty-fourth via hole Via24 and the twenty-sixth via hole Via26. The auxiliary electrode 40 is sequentially coupled to the connecting pattern 41 through the twenty-fifth via hole Via25 and the twenty-seventh via hole Via27. The connecting pattern 41 is sequentially coupled to the second electrode layer through the twenty-eighth via hole Via28 and the twenty-ninth via hole Via29.

As shown in FIG. 23, a schematic diagram of an aperture region 60 of a sub-pixel is shown, as well as a non-aperture region 61 near the aperture region 60.

As shown in FIG. 1, in some embodiments, the data writing transistor T1, the compensation transistor T2 and the reset transistor T3 all include a dual-gate structure, which can effectively reduce leakage current.

As shown in FIG. 1, in some embodiments, the writing control transistor T_com includes a single-gate structure.

Since the data writing transistor T1 is connected between the data line DA and the writing control transistor T_com, when the writing control transistor T_com is turned off, it can close the leakage path of the data writing transistor T1. The writing control transistor T_com adopts a single-gate structure design, which is beneficial to save the layout area.

Embodiments of the present disclosure also provide a display device, including the display substrate provided by the foregoing embodiments.

It should be noted that the display device can be: any product or component having a display function, such as a television, a monitor, a digital photo frame, a mobile phone, a tablet computer, etc., wherein the display device further includes a flexible circuit board, a printed circuit board, and a back plate, etc.

Exemplarily, the display device includes an organic light-emitting diode display device, but is not limited thereto.

In the display substrate provided by the foregoing embodiments, by arranging the first connection structure and the second connection structure both located in the non-aperture region of the sub-pixel, it is avoided that the first connection structure and the second connection structure occupy the space of the aperture region, ensuring the aperture ratio of the display substrate, and avoiding the first connection structure and the second connection structure from affecting the flatness of the light-emitting element.

Moreover, in the display substrate provided by the foregoing embodiments, by arranging the orthographic projection of the first connection structure onto the base substrate to be arranged with the orthographic projection of the second connection structure onto the base substrate along a first direction and arranging the orthographic projection of the second connection structure onto the base substrate with an aperture region of the sub-pixel along a second direction, the first connection structure and the second connection structure are both located on the same side of the aperture region along the second direction, and the first connection structure and the second connection structure occupy a small space along the second direction. Thus, the size of the aperture region along the second direction can be optimized, effectively improving the aperture ratio of the display substrate, and improving the service life of the display substrate.

The display device provided by embodiments of the present disclosure has same beneficial effects when including the foregoing display substrate. Details are not repeated here.

Referring to FIG. 1, FIG. 2, FIG. 3, FIG. 5, and FIG. 21, embodiments of the present disclosure provide a display substrate, including: a base substrate, and a plurality of repeating units and data lines DA arranged on the base substrate, the plurality of repeating units are divided into a plurality of columns of repeating unit columns:
each repeating unit includes a plurality of sub-pixels, the sub-pixels include a sub-pixel driving circuit, the sub-pixel driving circuit includes a data writing transistor T1, a writing control transistor T_com and a driving transistor DRT: a first electrode of the data writing transistor T1 is coupled to the corresponding data line DA, a second electrode of the data writing transistor T1 is coupled to a first electrode of the writing control transistor T_com, and a second electrode of the writing control transistor T_com is coupled to a gate electrode of the driving transistor DRT;
the display substrate further includes: a plurality of control regions (such as control regions 1 to X) and a plurality of partition control lines G_com; the control region includes at least one column of repeating unit columns; the partition control lines G_com are respectively coupled to gate electrodes of the writing control transistors T_com included in each repeating unit in the corresponding control regions.

Exemplarily, the display substrate includes a plurality of repeating units, and the plurality of repeating units are distributed in an array. The repeating unit includes a plurality of sub-pixels arranged along the first direction, for example: the repeating unit includes six sub-pixels arranged along the first direction. The six sub-pixels include BRGBRG arranged along the first direction, wherein B represents a blue sub-pixel, R represents a red sub-pixel, and G represents a green sub-pixel.

Exemplarily, the plurality of sub-pixels included in the plurality of repeating units are distributed in an array, the plurality of sub-pixels can be divided into a plurality of columns of sub-pixel columns, and the plurality of columns of sub-pixel columns correspond to the plurality of data lines DA included in the display substrate one by one.

Exemplarily, the sub-pixel includes a sub-pixel driving circuit and a light-emitting element EL, the sub-pixel driving circuit is coupled to the light-emitting element EL for providing a driving signal to the light-emitting element EL to drive the light-emitting element EL to emit light.

Exemplarily, the sub-pixel driving circuit includes a data writing transistor T1, a writing control transistor T_com and a driving transistor DRT: a first electrode of the data writing transistor T1 is coupled to the corresponding data line DA, a second electrode of the data writing transistor T1 is coupled to a first electrode of the writing control transistor T_com, and a second electrode of the writing control transistor T_com is coupled to a gate electrode of the driving transistor DRT: when both the data writing transistor T1 and the writing control transistor T_com are turned on, the data signal transmitted by the data line DA can be written into the gate electrode of the driving transistor DRT: when either the data writing transistor T1 or the writing control transistor T_com is turned off, the data signal cannot be transmitted to the gate electrode of the driving transistor DRT.

Exemplarily, the display substrate further includes a plurality of control regions and a plurality of partition control lines G_com, and the plurality of control regions corresponds one-to-one to the plurality of partition control lines G_com. The partition control lines G_com are respectively coupled to gate electrodes of the writing control transistors T_com included in each repeating unit column in the corresponding control regions, for controlling whether the writing control transistors T_com included in each repeating unit column in the corresponding control regions are turned on or off.

According to the specific structure of the foregoing display substrate, it can be seen that in the display substrate provided by embodiments of the present disclosure, a plurality of control regions are included. Each control region includes at least one column of repeating unit columns, and the partition control lines G_com are respectively coupled to gate electrodes of the writing control transistors T_com included in each repeating unit column in the corresponding control regions. By each partition control line G_com, all the writing control transistors T_com in the corresponding control region can be controlled to be turned on or off, so as to achieve the effect of controlling whether that region achieves high refresh rate.

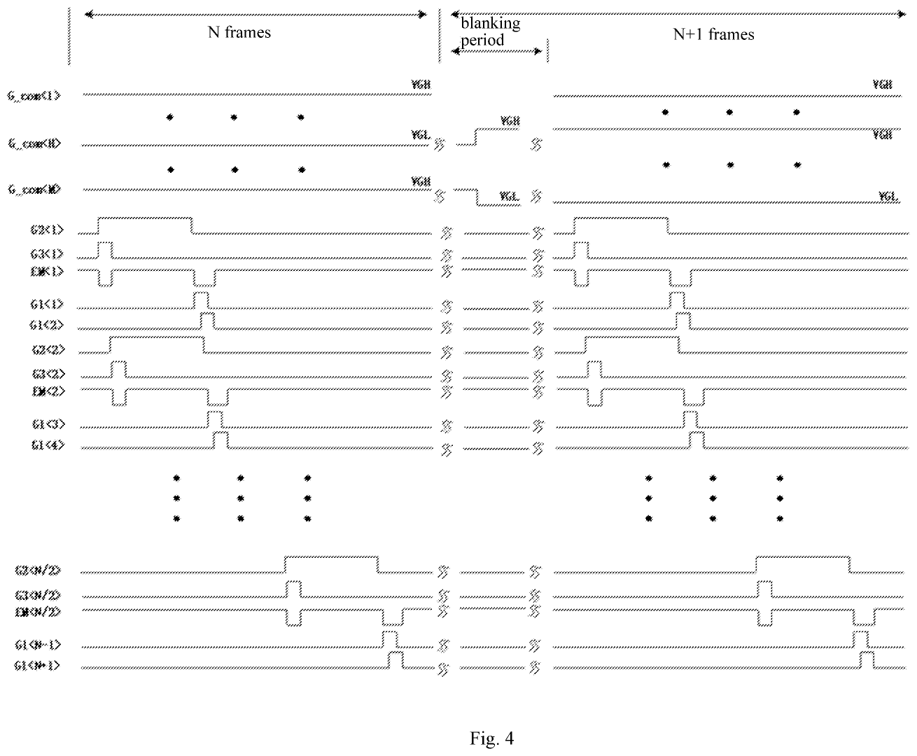

More specifically, as shown in FIG. 3 and FIG. 4, taking a display substrate including X control regions as an example.

During the N-th frame display period: the control signals transmitted by the first partition control line G_com<1> and the M-th partition control line G_com<M> are both at a valid level VGH. All the writing control transistors T_com included in the first control region corresponding to the first partition control line G_com<1> are turned on and all the writing control transistors T_com included in the M-th control region corresponding to the M-th partition control line G_com<M> are turned on. It ensures that the first control region and the M-th control region are regions that can achieve normal refresh, and high refresh operation of the first control region and the M-th control region can be achieved during scanning of the display substrate row by row. The control signal transmitted by the H-th partition control line G_com<H> is at an invalid level VGL. All the writing control transistors T_com included in the H-th control region corresponding to the H-th partition control line G_com<H> are turned off. High refresh operation of the H-th control region cannot be achieved during scanning of the display substrate row by row, so that the H-th control region does not refresh in the N-th frame. Its display picture is not updated within the N-th frame, and the saved data amount is provided to the high refresh region, achieving a partitioned high refresh effect. It should be noted that M and H are both positive integers greater than 1 and less than X.

During a blanking period of time, by controlling the level of the control signal transmitted by the partition control line G_com, partition selection for N+1 frames is performed. It should be noted that the blanking period of time is located at a beginning or an end of each frame display period.

During the (N+1)-th frame display period: the control signals transmitted by the first partition control line G_com<1> and the H-th partition control line G_com<H> are both at a valid level VGH. All the writing control transistors T_com included in the first control region corresponding to the first partition control line G_com<1> are turned on and all the writing control transistors T_com included in the H-th control region corresponding to the H-th partition control line G_com<H> are turned on. It ensures that the first control region and the H-th control region are regions that can achieve normal refresh, and high refresh operation of the first control region and the M-th control region can be achieved during scanning of the display substrate row by row. The control signal transmitted by the M-th partition control line G_com<M> is at an invalid level VGL. All the writing control transistors T_com included in the M-th control region corresponding to the M-th partition control line G_com<M> are turned off. High refresh operation of the M-th control region cannot be achieved during scanning of the display substrate row by row, so that the M-th control region does not refresh in the M-th frame, and its display picture is not updated within the M-th frame, and saved data amount is provided to high refresh region, achieving a partitioned high refresh effect.

It should be noted that considering that the partition control line G_com has a large load, the control signal transmitted by the partition control line G_com can be adjusted immediately when entering the blanking period of time at the end of the N-th frame.

In the display substrate provided by embodiments of the present disclosure, by arranging the control regions and the partition control line G_com, the large size display substrate can also achieve the function of high refresh rate of the display substrate well.

It should be noted that the number of rows represented by the brackets in FIG. 4, such as: G1<1> represents the first row of the first scan line, G2<1> represents the first row of the second scan line, G3<1> represents the first row of the third scan line, and EM<1> represents the first row of the light-emitting control line.

As shown in FIG. 3, FIG. 5, FIG. 8, FIG. 11, FIG. 15, FIG. 19 and FIG. 21, in some embodiments, the partition control line G_com includes: a control bus 10 and at least one control branch line 11:

The control branch line 11 is respectively coupled to gate electrodes of each writing control transistor T_com included in a corresponding column of repeating unit columns in the corresponding control region. The control bus 10 is coupled to the at least one control branch line 11.

Exemplarily, the control branch lines 11 included in the partition control line G_com correspond one-to-one to the repeating unit columns included in their corresponding control regions. The control branch line 11 is respectively coupled to gate electrodes of each writing control transistor T_com included in a corresponding column of repeating unit columns in the corresponding control region for controlling whether each writing control transistor T_com included in a corresponding column of repeating unit columns is turned on or off.

Exemplarily, in a same partition control line G_com, the control bus 10 and each control branch line 11 are respectively coupled. Exemplarily, in a same partition control line G_com, the control bus 10 and each control branch line 11 form an integrated structure.

Exemplarily, the display substrate further includes a driving chip. The control bus 10 is located on a same side of the display substrate as the driving chip, and is coupled to the driving chip for receiving a control signal provided by the driving chip and transmitting a received control signal to each coupled control branch line 11, thereby controlling whether the writing control transistors T_com in corresponding control regions are turned on or off.

In the display substrate provided by the foregoing embodiments, by arranging the partition control line G_com to include the control bus 10 and the control branch lines 11, not only can transmission of a control signal be better achieved, but also layout difficulty of the partition control line G_com can be reduced, ensuring the reliability of coupling between the partition control line G_com and the gate electrodes of the writing control transistors T_com.

As shown in FIG. 3, FIG. 5, FIG. 8, FIG. 11, FIG. 15, FIG. 19 and FIG. 21, in some embodiments, the control branch line 11 includes: a first branch line 111 and a plurality of second branch lines 112. The second branch lines 112 include at least a portion extending along a first direction, and the plurality of second branch lines 112 are arranged along a second direction. The first branch line 111 includes at least a portion extending along the second direction, and the first branch line 111 is respectively coupled to the plurality of second branch lines 112. The first branch line 111 is coupled to the control bus 10. The first direction intersects with the second direction. The second branch lines 112 are respectively coupled to gate electrodes of each writing control transistor T_com included in the corresponding repeating unit.

Exemplarily, the first direction includes a horizontal direction, and the second direction includes a vertical direction.

Exemplarily, in the control region, the control branch line 11 corresponds one-to-one to the repeating unit column, and the plurality of second branch lines 112 included in the control branch line 11 correspond one-to-one to the plurality of repeating units included in the corresponding repeating unit column. The repeating unit includes a plurality of sub-pixels arranged along the first direction, and the sub-pixel driving circuit included in the sub-pixel includes a writing control transistor T_com. The second branch line 112 is respectively coupled to gate electrodes of each writing control transistor T_com included in the corresponding repeating unit. For example, the second branch line 112 is respectively coupled to gate electrodes of six writing control transistors T_com included in the corresponding repeating unit, for controlling whether the six writing control transistors T_com are turned on or off.

Exemplarily, the first branch line 111 included in the control branch line 11 is located in a middle region of the corresponding repeating unit column, that is, in the repeating unit column corresponding to the first branch line 111, along the first direction, the number of sub-pixels on both sides of the first branch line 111 is same. For example: along the first direction, there are three sub-pixels on both sides of the corresponding first branch line 111 in each repeating unit.

Exemplarily, in the same control branch line 11, the orthographic projection of the first branch line 111 on the base substrate respectively forms overlapping regions with the orthographic projections of each of the second branch lines 112 on the base substrate, and the first branch line 111 is coupled to the corresponding second branch line 112 through a via hole in the corresponding overlapping region.

In the display substrate provided by this embodiment, by setting that the control branch line 11 includes: the first branch line 111 and a plurality of second branch lines 112: not only can transmission of a control signal be better achieved, but also layout difficulty of the control branch line 11 can be reduced, ensuring reliability of coupling between the control branch line 11 and gate electrodes of the writing control transistors T_com.

In some embodiments, in the same control region, the second branch lines 112 adjacent along the first direction are coupled to each other.

Exemplarily, in the same control region, along the first direction, each of the second branch lines 112 in the same row are sequentially connected head to tail. Exemplarily, in the same control region, along the first direction, each of the second branch lines 112 in the same row form an integrated structure.

Exemplarily, in adjacent control regions, along the first direction, there is a break between adjacent second branch lines 112.

In the display substrate provided by the foregoing embodiments, by arranging that in the same control region, along the first direction, adjacent second branch lines 112 are coupled to each other, so that in the same control region, the control branch line 11 can form a grid-like structure, which is beneficial to reduce the overall load of the partition control line G_com and reduce the voltage drop of the partition control line G_com.

In some embodiments, in the same control region, the second branch lines 112 adjacent along the first direction are independent of each other.

As shown in FIG. 11, in some embodiments, the display substrate further includes a plurality of power lines VDD, and the orthographic projection of the second branch line 112 on the base substrate does not overlap with the orthographic projection of the power line VDD on the base substrate.

Exemplarily, the plurality of power lines VDD are arranged along the first direction, and the power lines VDD include at least a portion extending along the second direction. Along the first direction, the power lines VDD are alternately arranged with the repeating unit columns.

Exemplarily, the display substrate further includes a plurality of power compensation lines 30. The plurality of power compensation lines 30 are arranged along the second direction, and the power compensation lines 30 include at least a portion extending along the first direction. The power compensation lines 30 are respectively coupled to the plurality of power lines VDD, and the power compensation lines 30 and the power lines VDD jointly form a grid-like structure, so as to reduce voltage drop of the power lines VDD.

Exemplarily, there is an overlapping region between the orthographic projection of the power compensation line 30 on the base substrate and the orthographic projection of the power line VDD on the base substrate, and the power compensation line 30 is coupled to the power line VDD through a via hole in that overlapping region.

In the display substrate provided by the foregoing embodiments, by arranging that along the first direction, adjacent second branch lines 112 are independent of each other, and that on the base substrate, there is no overlap between the orthographic projection of the second branch line 112 and the orthographic projection of the power line VDD, so that the control branch line 11 forms a non-grid-like structure and can avoid the power line VDD. This not only reduces the risk of short circuit between the control branch line 11 and the power line VDD, but also reduces the parasitic capacitance formed between the control branch line 11 and the power line VDD.

As shown in FIG. 11, in some embodiments, the orthographic projection of the data line DA on the base substrate has a first overlapping region with the orthographic projection of the second branch line 112 on the base substrate, and the areas of the first overlapping regions formed by each of the data lines DA are the same.

Exemplarily, the data line DA is alternately arranged with the sub-pixel columns in the display substrate along the first direction. The data line DA includes at least a portion extending along the second direction.

Exemplarily, the data line DA and the second branch line 112 are arranged in different layers. The sum of the areas of the first overlapping regions formed between each of the data lines DA and the plurality of second branch lines 112 are the same.

In the display substrate provided by the foregoing embodiments, by arranging the sum of the areas of the first overlapping regions formed between each of the data lines DA and the plurality of second branch lines 112 to be the same, it is ensured that the loads of the data lines DA connected to the sub-pixels of various colors in the display substrate are the same. It better ensures the uniformity of the display image of the display substrate.

In some embodiments, the first branch line 111 is made of the first gate metal layer in the display substrate, and the second branch line 112 is made of the first source-drain metal layer in the display substrate.

As shown in FIG. 24, in some embodiments, the display substrate includes: a buffer layer 71, an active layer, a first gate electrode insulating layer, a first gate metal layer, a second gate electrode insulating layer, a second gate metal layer, an interlayer insulating layer ILD, a first source-drain metal layer, a first organic layer Resin1, a first passivation layer PVX1, a second source-drain metal layer, a second passivation layer PVX2, a second organic layer Resin2, a first electrode layer 42, a first pixel definition layer PDL1, a second pixel definition layer PDL2, a light-emitting functional layer, a second electrode layer 43 and an encapsulation layer sequentially stacked on the base substrate 70 in a direction away from the base substrate 70. FIG. 24 also schematically shows the first connection structure 81, the second connection structure 82 and the third connection structure 83. The second electrode layer 43 receives a negative power supply signal VSS.

In the display substrate provided by the foregoing embodiments, by arranging the first branch line 111 to be made of the first gate metal layer, the first branch line 111 can be formed in the same patterning process as other structures made of the first gate metal layer in the display substrate, thereby effectively simplifying the manufacturing process flow of the display substrate.

In the display substrate provided by the foregoing embodiments, by arranging the second branch line 112 to be made of the first source-drain metal layer in the display substrate, the second branch line 112 can be formed in the same patterning process as other structures made of the first source-drain metal layer in the display substrate, thereby effectively simplifying the manufacturing process flow of the display substrate.

In the display substrate provided by the foregoing embodiments, by arranging the partition control line G_com to include the control bus 10 and the control branch line 11, and arranging the control branch line 11 to include the first branch line 111 and the plurality of second branch lines 112, the partition control line G_com is designed in parallel within the control region. Its equivalent resistance is small, and the first branch line 111 is made of the first gate metal layer in the display substrate. The square resistance of the first gate metal layer is large, and has a small influence on the parasitic resistance. Moreover, by arranging the first branch line 111 to be made of the first gate metal layer in the display substrate, and arranging the second branch line 112 to be made of the first source-drain metal layer in the display substrate, it effectively reduces the parasitic capacitance formed between the partition control line G_com and the structures made of the second source-drain metal layer, thereby optimizing the load of the partition control line G_com and achieving partition control optimization effect.

As shown in FIG. 1, FIG. 5, FIG. 6, FIG. 7, FIG. 11, FIG. 15, FIG. 19 and FIG. 21, in some embodiments, the display substrate further includes: a plurality of first scan lines G1, a plurality of second scan lines G2, a plurality of third scan lines G3, a plurality of light-emitting control lines EM, a power line VDD, a reference signal line Vref and an initialization signal line Vini:
the sub-pixel driving circuit further includes: a compensation transistor T2, a reset transistor T3, a light-emitting control transistor T_em and a storage capacitor Cst;
a gate electrode of the data writing transistor T1 is coupled to the corresponding first scan line G1;
a gate electrode of the compensation transistor T2 is coupled to the corresponding second scan line G2, a first electrode of the compensation transistor T2 is coupled to the reference signal line Vref, and a second electrode of the compensation transistor T2 is coupled to a first electrode of the writing control transistor T_com;
a gate electrode of the reset transistor T3 is coupled to the corresponding third scan line G3, a first electrode of the reset transistor T3 is coupled to the initialization signal line Vini, and a second electrode of the reset transistor T3 is coupled to the second electrode of the driving transistor DRT;
a gate electrode of the light-emitting control transistor T_em is coupled to the corresponding light-emitting control line EM, a first electrode of the light-emitting control transistor T_em is coupled to the power line VDD, and a second electrode of the light-emitting control transistor T_em is coupled to the first electrode of the driving transistor DRT;
a first electrode plate Cst1 of the storage capacitor Cst is coupled to the gate electrode of the driving transistor DRT, and a second electrode plate Cst2 of the storage capacitor Cst is coupled to the second electrode of the driving transistor DRT.

Exemplarily, the initialization signal line Vini includes a plurality of first initial portions 21 and a plurality of second initial portions 22. The plurality of first initial portions 21 are arranged along the second direction. The plurality of second initial portions 22 are arranged along the first direction. The first initial portion 21 includes at least a portion extending along the first direction. The second initial portion 22 includes at least a portion extending along the second direction. The first initial portion 21 is coupled to each of the second initial portions 22 respectively. So that, the initialization signal line Vini forms a grid-like structure, thereby effectively reducing the voltage drop of the initialization signal line Vini.

As shown in FIG. 5, exemplarily, the active layer is used to form the channel portions included in each of the transistors, the first electrodes and the second electrodes.

As shown in FIG. 5, exemplarily, the first gate metal layer is used to form the gate electrodes of each of the transistors, the first branch line 111 and the second initial portion 22.

As shown in FIG. 7, exemplarily, the second gate metal layer is used for the second substrate of the storage capacitor Cst.

As shown in FIG. 10, exemplarily, the first source-drain metal layer is used to form some conductive connection portions, the reference signal line Vref, the first scan line G1, the second scan line G2, the third scan line G3, the light-emitting control line EM and the first initial portion 21. The reference signal line Vref, the second scan line G2, the first scan line G1, the second branch line 112, light-emitting control line EM, the power compensation line 30, the third scan line G3 and the first initial portion 21 coupled to the same repeating unit are arranged along the second direction in sequence.

Exemplarily, the reference signal line Vref, the first scan line G1, the second scan line G2, the third scan line G3 and the light-emitting control line EM all include at least a portion extending along the first direction.

As shown in FIG. 14, exemplarily, the second source-drain metal layer is used to form the power line VDD, the data line DA, some conductive connection portions and the auxiliary electrode 40. Exemplarily, the auxiliary electrode 40 includes at least a portion extending along the second direction, and the auxiliary electrode 40 is coupled to the second electrode layer through a connecting pattern 41 made of indium tin oxide material, thereby effectively reducing the voltage drop of the second electrode layer.

As shown in FIG. 1, exemplarily, the sub-pixel driving circuit includes: a data writing transistor T1, a writing control transistor T_com, a driving transistor DRT, a compensation transistor T2, a reset transistor T3, a light-emitting control transistor T_em, a storage capacitor Cst and an intrinsic capacitor C1 of the light-emitting element EL.

As shown in FIG. 9, it schematically shows via holes formed on the interlayer insulating layer. As shown in FIG. 5 to FIG. 10, a gate electrode of the compensation transistor T2 is coupled to the corresponding second scan line G2 through a second via hole Via2, and a first electrode of the compensation transistor T2 is coupled to the reference signal line Vref through a first via hole Via1.

A gate electrode of the data writing transistor T1 is coupled to the corresponding first scan line G1 through a third via hole Via3. A first electrode of the data writing transistor T1 is coupled to a fourth conductive connection portion 54 through a ninth via hole Via9.

A gate electrode of the writing control transistor T_com is coupled to a partition control line G_com through a fourth via hole Via4, and a second electrode of the writing control transistor T_com is coupled to a first conductive connection portion 51 through a fifth via hole Via5. The first conductive connection portion 51 is coupled to a gate electrode of the driving transistor DRT through a sixth via hole Via6. The gate electrode of the driving transistor DRT is reused as a first electrode plate Cst1 of the storage capacitor Cst.

A second electrode of the driving transistor DRT is coupled to a second conductive connection portion 52 through a seventh via hole Via7. The second conductive connection portion 52 is coupled to a second electrode plate Cst2 of the storage capacitor Cst through an eighth via hole Via8. The second electrode plate Cst2 of the storage capacitor Cst is coupled to a third conductive connection portion 53 through a tenth via hole Via10. The third conductive connection portion 53 is coupled to a second electrode of the reset transistor T3 through a fifteenth via hole Via15.

A gate electrode of the light-emitting control transistor T_em is coupled to the corresponding light-emitting control line EM through an eleventh via hole Via11. A first electrode of the light-emitting control transistor T_em is coupled to the power line VDD through a twelfth via hole Via12.

A gate electrode of the reset transistor T3 is coupled to the third scan line G3 through a fourteenth via hole Via14. A first electrode of the reset transistor T3 is coupled to the first initial portion 21 through a thirteenth via hole Via13.

The first branch line 111 is coupled to the second branch line 112 through a twenty-second via hole Via22. The first initial portion 21 is coupled to the second initial portion 22 through a twenty-third via hole Via23.

As shown in FIG. 12, a schematic diagram of via holes formed on the first organic layer is shown. As shown in FIG. 13, a schematic diagram of via holes formed on the first passivation layer is shown.

As shown in FIG. 11 to FIG. 14, the second conductive connection portion 52 is sequentially coupled to the fifth conductive connection portion 55 through the seventeenth via hole Via17 and the twentieth via hole Via20. The fourth conductive connection portion 54 is sequentially coupled to the data line DA through the sixteenth via hole Via16 and the nineteenth via hole Via19. The power compensation line 30 is sequentially coupled to the power line VDD through the eighteenth via hole Via18 and the twenty-first via hole Via21.

As shown in FIG. 16, a schematic diagram of via holes formed on the second passivation layer is shown. As shown in FIG. 17, a schematic diagram of via holes formed on the second organic layer is shown.

As shown in FIG. 15 to FIG. 22, the fifth conductive connection portion 55 is sequentially coupled to the corresponding first electrode in the first electrode layer 42 through the twenty-fourth via hole Via24 and the twenty-sixth via hole Via26. The auxiliary electrode 40 is sequentially coupled to the connecting pattern 41 through the twenty-fifth via hole Via25 and the twenty-seventh via hole Via27. The connecting pattern 41 is sequentially coupled to the second electrode layer through the twenty-eighth via hole Via28 and the twenty-ninth via hole Via29.

As shown in FIG. 23, a schematic diagram of an aperture region 60 of a sub-pixel is shown, as well as a non-aperture region 61 near the aperture region 60.

As shown in FIG. 1, in some embodiments, the data writing transistor T1, the compensation transistor T2 and the reset transistor T3 all include a dual-gate structure, which can effectively reduce leakage current.

As shown in FIG. 1, in some embodiments, the writing control transistor T_com includes a single-gate structure.

Since the data writing transistor T1 is connected between the data line DA and the writing control transistor T_com, when the writing control transistor T_com is turned off, it can close the leakage path of the data writing transistor T1. The writing control transistor T_com adopts a single-gate structure design, which is beneficial to save layout area.

The present disclosure also provides a driving method for a display substrate, for driving the display substrate provided by the foregoing embodiments, the driving method including:
in the display period of the N-th frame, at least some of the plurality of partition control lines G_com in the display substrate transmit partition control signals at a valid level, the writing control transistors T_com coupled to the at least some partition control lines G_com are turned on, and the plurality of sub-pixels are scanned row by row, to achieve row-by-row data signal writing;
in the display period of the (N+1)-th frame, the level of the partition control signal transmitted by the plurality of partition control lines G_com changes, so that the writing control transistors T_com coupled to the partition control lines G_com transmitting the valid level partition control signal are turned on, and the plurality of sub-pixels are scanned row by row, to achieve row-by-row data signal writing.

An example in which a display substrate includes X control regions, is provided hereinafter.

Exemplarily, in the display period of the N-th frame, the control signals transmitted by the first partition control line G_com<I> and the M-th partition control line G_com<M> in the display substrate are both at a valid level VGH. All the writing control transistors T_com included in the first control region corresponding to the first partition control line G_com<1> are turned on and all the writing control transistors T_com included in the M-th control region corresponding to the M-th partition control line G_com<M> are turned on. It ensures that the first control region and the M-th control region are regions that can achieve normal refresh, and when scanning the display substrate row by row, high refresh operation of the first control region and the M-th control region can be achieved. In the display period of the (N+1)-th frame, the level of the partition control signal transmitted by the plurality of partition control lines G_com changes, so that the control signals transmitted by the first partition control line G_com<1> and the H-th partition control line G_com<H> are both at a valid level VGH. All the writing control transistors T_com included in the first control region corresponding to the first partition control line G_com<1> are turned on and all the writing control transistors T_com included in the H-th control region corresponding to the H-th partition control line G_com<H> are turned on. It ensures that the first control region and the H-th control region are regions that can achieve normal refresh, and when scanning the display substrate row by row, high refresh operation of the first control region and the H-th control region can be achieved.

When scanning the display substrate row by row to write data signals, according to actual needs, it is possible to control every two rows or every four rows of sub-pixel driving circuits to achieve reset and compensation simultaneously.

When driving the display substrate using the driving method provided by embodiments of the present disclosure, by controlling whether all the writing control transistors T_com in corresponding control regions are turned on through each partition control line G_com, it is possible to achieve controlling whether high refresh rate is achieved in that region, so that large size display substrates can also achieve high refresh rate function of display substrates well.

In some embodiments, the driving method further includes:
a blanking period of time, the blanking period of time is located at the beginning or end of each frame display period: in the blanking period of time, the level of the partition control signal transmitted by the plurality of partition control lines is adjusted.

Exemplarily, at the end of the N-th frame, when entering the blanking period of time of the (N+1)-th frame, the control signal transmitted by the partition control line G_com is immediately adjusted.

Embodiments of the present disclosure also provide a display device, including the display substrate provided by the foregoing embodiments.

It should be noted that the display device can be: a TV, a monitor, a digital photo frame, a mobile phone, a tablet computer or any other product or component with a display function, wherein the display device also includes a flexible circuit board, a printed circuit board and a backplane, etc.

Exemplarily, the display device includes an organic light-emitting diode display device, but is not limited thereto.

In the display substrate provided by the foregoing embodiments, the display substrate includes a plurality of control regions. Each control region includes at least one column of repeating unit columns, and the partition control lines are coupled to the gate electrodes of the writing control transistors included in each repeating unit column in corresponding control regions respectively. By controlling whether all writing control transistors in corresponding control regions are turned on through each partition control line, it is possible to achieve controlling whether high refresh rate is achieved in that region. In the display substrate provided by the foregoing embodiments, by arranging the control regions and partition control lines, large size display substrates can also achieve high refresh rate function of display substrates well.

The display devices provided by embodiments of the present disclosure also have the foregoing beneficial effects when including the foregoing display substrate. Details are not further described herein.

It should be noted that a signal line extending along a certain direction means: the signal line includes a main portion and a secondary portion connected to the main portion, the main portion is a line, a line segment or a strip-shaped body, the main portion extends along a certain direction, and the length of the main portion extending along a certain direction is greater than the length of the secondary portion extending along other directions.

It should be noted that “the same film layer” in an embodiment of the present disclosure may refer to a film layer located on the same structural layer. Alternatively, for example, the film layer at the same level may be a film layer formed to have a particular pattern by using the same film-forming process. The film layer may then be patterned by one patterning process using the same mask to form the desired layer structure. Depending on different particular patterns, the one patterning process may include multiple exposing, developing, or etching processes. Further, as an example, a particular pattern in the formed layer structure may be continuous or discontinuous. As other example, these particular patterns may be at different heights or have different thicknesses.

In the method embodiments of the invention, the sequential number of each step is not used to limit the order of the steps. Instead, the order of the steps may be changed by those skilled in the art without any inventive effort and is thus under the protection of the invention.

It should be noted that the various embodiments in the present description are described in a progressive manner, and the various embodiments may refer to each other for the same or similar parts, and each embodiment focuses on differences from other embodiments. Especially, for the method embodiment, since it is basically similar to the product embodiment, the description is relatively simple, and the relevant parts can be referred to the description of the product embodiment.

Unless otherwise defined, technical terms or scientific terms used in the present disclosure shall have the common meanings understood by those with ordinary skills in the field to which the present disclosure belongs. “First”, “second” and similar words used in the present disclosure do not indicate any order, quantity, or importance, but are only used to distinguish different components. “Include” or “include” and other similar words mean that the element or item before the word encompasses the element or item and their equivalents listed after the word, but does not exclude other elements or items. Similar words such as “coupled” or “connected” are not limited to physical or mechanical connections, but may include electrical connections, whether direct or indirect. “Up”, “down”, “left”, “right”, etc. are only used to indicate a relative position relationship. When an absolute position of a described object changes, the relative position relationship may also change accordingly.

It should be appreciated that, in the case that such an element as layer, film, region or substrate is arranged “on” or “under” another element, it may be directly arranged “on” or “under” the other element, or an intermediate element may be arranged therebetween.

In descriptions of the implementation modes, the specific features, structures, materials, or characteristics described may be combined in any suitable manner in any one or more embodiments or examples.

The foregoing are only specific embodiments of the present disclosure, but the protection scope of the present disclosure is not limited thereto. In the technical scope disclosed by the present disclosure, changes or substitutions easily thought by any skilled in the art are all covered in the protection scope of the present disclosure. Therefore, the protection scope of the present disclosure should be the protection scope of the claims.

1. A display substrate, comprising: a base substrate, a plurality of data lines and sub-pixels on the base substrate; wherein the sub-pixel comprises a sub-pixel driving circuit and a light-emitting element; the sub-pixel driving circuit comprises a driving transistor and a data writing transistor, and the light-emitting element comprises a first electrode;
a second electrode of the driving transistor is coupled to the corresponding first electrode through a first connection structure; a first electrode of the data writing transistor is coupled to the corresponding data line through a second connection structure;
the first connection structure and the second connection structure are in a non-aperture region of the sub-pixel; and an orthographic projection of the first connection structure onto the base substrate and an orthographic projection of the second connection structure onto the base substrate are arranged along a first direction;
the orthographic projection of the second connection structure onto the base substrate and an aperture region of the sub-pixel are arranged along a second direction, and the second direction intersects the first direction.

2. The display substrate according to claim 1, wherein the first connection structure comprises: a second conductive connection portion, a first via-hole structure, a fifth conductive connection portion and a second via-hole structure;
the second conductive connection portion is coupled to the second electrode of the driving transistor, the second conductive connection portion is coupled to the fifth conductive connection portion through the first via-hole structure, and the fifth conductive connection portion is coupled to the corresponding first electrode through the second via-hole structure.

3. The display substrate according to claim 2, wherein the second connection structure comprises: a fourth conductive connection portion and a third via-hole structure; the fourth conductive connection portion is coupled to the first electrode of the data writing transistor, and the fourth conductive connection portion is coupled to the corresponding data line through the third via-hole structure.

4. The display substrate according to claim 3, wherein the display substrate further comprises a first organic layer and a second organic layer sequentially stacked in a direction away from the base substrate, the first via-hole structure is defined through the first organic layer, and the second via-hole structure is defined through the second organic layer;
the second conductive connection portion is between the first organic layer and the base substrate, and the fifth conductive connection portion is between the first organic layer and the second organic layer.

5. The display substrate according to claim 4, wherein the third via-hole structure is defined through the first organic layer; and the fourth conductive connection portion is between the first organic layer and the base substrate.

6. The display substrate according to claim 5, wherein the display substrate further comprises: a first passivation layer and a second passivation layer; the first passivation layer is between the first organic layer and the second passivation layer, the second passivation layer is between the first passivation layer and the second organic layer;
the first via-hole structure and the third via-hole structure are both defined through the first passivation layer, and the second via-hole structure is defined through the second passivation layer; the fifth conductive connection portion is between the first passivation layer and the second passivation layer.

7. The display substrate according to claim 1, wherein the display substrate further comprises: an auxiliary electrode, a third connection structure, and a second electrode layer; the auxiliary electrode is coupled to the second electrode layer through the third connection structure;
the third connection structure is in the non-aperture region of the sub-pixel; and an orthographic projection of the third connection structure onto the base substrate and the orthographic projection of the first connection structure onto the base substrate are arranged along the first direction.

8. The display substrate according to claim 1, wherein the display substrate further comprises: an auxiliary electrode, a third connection structure, and a second electrode layer; the auxiliary electrode is coupled to the second electrode layer through the third connection structure;
the third connection structure is in the non-aperture region of the sub-pixel, and an orthographic projection of the third connection structure onto the base substrate is at least partly staggered from the orthographic projection of the first connection structure onto the base substrate.

9. The display substrate according to claim 7- or 8, wherein the display substrate further comprises a second organic layer and a pixel definition layer sequentially stacked in a direction away from the base substrate;
the third connection structure comprises: a fourth via-hole structure, a connecting pattern and a fifth via-hole structure; the auxiliary electrode is between the second organic layer and the base substrate; at least a portion of the second electrode layer is at a side of the pixel definition layer facing away from the base substrate; at least a portion of the connecting pattern is between the second organic layer and the pixel definition layer; the fourth via-hole structure is defined through the second organic layer, and the fifth via-hole structure is defined through the pixel definition layer;
the connecting pattern is coupled to the auxiliary electrode through the fourth via-hole structure, and the connecting pattern is coupled to the second electrode layer through the fifth via-hole structure.

10. The display substrate according to claim 9, wherein the plurality of sub-pixels are divided into an array of repeating units, each repeating unit comprises two sub-units arranged along the first direction, and each sub-unit comprises the plurality of sub-pixels arranged along the first direction;
the orthographic projection of the auxiliary electrode onto the base substrate is located between orthographic projections of the two sub-units onto the base substrate.

11. The display substrate according to claim 10, wherein the display substrate further comprises a power line and a power compensation line;
the sub-pixel driving circuit further comprises a light-emitting control transistor; a first electrode of the light-emitting control transistor is coupled to the power compensation line, and a second electrode of the light-emitting control transistor is coupled to a first electrode of the driving transistor;
the power compensation line is coupled to the power line through a sixth via-hole structure, and the sixth via-hole structure is in the non-aperture region of the sub-pixel.

12. The display substrate according to claim 11, wherein the display substrate further comprises a first organic layer, the power compensation line is between the first organic layer and the base substrate, the power line is on a side of the first organic layer facing away from the base substrate, and the sixth via-hole structure is defined through the first organic layer.

13. The display substrate according to claim 11, wherein orthographic projections of the power lines onto the base substrate and orthographic projections of the repeating units onto the base substrate are alternately arranged along the first direction.

14. The display substrate according to claim 1, wherein the display substrate further comprises: a plurality of light-emitting control lines, power lines, an initialization signal line, a reference signal line, a plurality of first scan lines, a plurality of second scan lines, a plurality of third scan lines and a plurality of partition control lines;
the sub-pixel driving circuit further comprises: a compensation transistor, a reset transistor, the light-emitting control transistor, a writing control transistor and a storage capacitor;
a gate electrode of the data writing transistor is coupled to the corresponding first scan line, and a second electrode of the data writing transistor is coupled to a first electrode of the writing control transistor;
a second electrode of the writing control transistor is coupled to a gate electrode of the driving transistor, and a gate electrode of the writing control transistor is coupled to the corresponding partition control line;
a gate electrode of the compensation transistor is coupled to the corresponding second scan line, a first electrode of the compensation transistor is coupled to the reference signal line, and a second electrode of the compensation transistor is coupled to the first electrode of the writing control transistor;
a gate electrode of the reset transistor is coupled to the corresponding third scan line, a first electrode of the reset transistor is coupled to the initialization signal line, and a second electrode of the reset transistor is coupled to the second electrode of the driving transistor;
a gate electrode of the light-emitting control transistor is coupled to the corresponding light-emitting control line, the first electrode of the light-emitting control transistor is coupled to the power line, and the second electrode of the light-emitting control transistor is coupled to the first electrode of the driving transistor;
a first electrode plate of the storage capacitor is coupled to the gate electrode of the driving transistor, and a second electrode plate of the storage capacitor is coupled to the second electrode of the driving transistor.

15. A display device, comprising a display substrate;
wherein the display substrate comprises: a base substrate, a plurality of data lines and sub-pixels on the base substrate; wherein the sub-pixel comprises a sub-pixel driving circuit and a light-emitting element; the sub-pixel driving circuit comprises a driving transistor and a data writing transistor, and the light-emitting element comprises a first electrode;
a second electrode of the driving transistor is coupled to the corresponding first electrode through a first connection structure; a first electrode of the data writing transistor is coupled to the corresponding data line through a second connection structure;
the first connection structure and the second connection structure are in a non-aperture region of the sub-pixel; and an orthographic projection of the first connection structure onto the base substrate and an orthographic projection of the second connection structure onto the base substrate are arranged along a first direction;
the orthographic projection of the second connection structure onto the base substrate and an aperture region of the sub-pixel are arranged along a second direction, and the second direction intersects the first direction.

16. The display device according to claim 15, wherein the first connection structure comprises: a second conductive connection portion, a first via-hole structure, a fifth conductive connection portion and a second via-hole structure;
the second conductive connection portion is coupled to the second electrode of the driving transistor, the second conductive connection portion is coupled to the fifth conductive connection portion through the first via-hole structure, and the fifth conductive connection portion is coupled to the corresponding first electrode through the second via-hole structure.

17. The display device according to claim 16, wherein the second connection structure comprises: a fourth conductive connection portion and a third via-hole structure; the fourth conductive connection portion is coupled to the first electrode of the data writing transistor, and the fourth conductive connection portion is coupled to the corresponding data line through the third via-hole structure.

18. The display device according to claim 17, wherein the display substrate further comprises a first organic layer and a second organic layer sequentially stacked in a direction away from the base substrate, the first via-hole structure is defined through the first organic layer, and the second via-hole structure is defined through the second organic layer;
the second conductive connection portion is between the first organic layer and the base substrate, and the fifth conductive connection portion is between the first organic layer and the second organic layer.

19. The display device according to claim 18, wherein the third via-hole structure is defined through the first organic layer; and the fourth conductive connection portion is between the first organic layer and the base substrate.

20. The display device according to claim 19, wherein the display substrate further comprises: a first passivation layer and a second passivation layer; the first passivation layer is between the first organic layer and the second passivation layer, the second passivation layer is between the first passivation layer and the second organic layer;
the first via-hole structure and the third via-hole structure are both defined through the first passivation layer, and the second via-hole structure is defined through the second passivation layer; the fifth conductive connection portion is between the first passivation layer and the second passivation layer.
